(19) United States
(12) Patent Application Publication
(10) Pub. No.: US 2013/0032199 A1
(43) Pub. Date: Feb. 7, 2013

(54) PHOTOVOLTAIC MODULE

(71) Applicants: Bruce Bengtson, Maplewood, MN (US); Kevin Crots, Perrysburg, OH (US); Wenlai Feng, Perrysburg, OH (US); Casimir P. Kotarba, III, Perrysburg, OH (US)

(72) Inventors: Bruce Bengtson, Maplewood, MN (US); Kevin Crots, Perrysburg, OH (US); Wenlai Feng, Perrysburg, OH (US); Casimir P. Kotarba, III, Perrysburg, OH (US)

(73) Assignee: FIRST SOLAR, INC., Perrysburg, OH (US)

(21) Appl. No.: 13/566,388

(22) Filed: Aug. 3, 2012

Related U.S. Application Data
(60) Provisional application No. 61/514,781, filed on Aug. 3, 2011.

(51) Int. Cl. H01L 31/048; H01R 43/00; H02G 3/18; H05K 13/00

(52) U.S. Cl. 136/251; 29/592.1; 29/854; 174/650

(57) ABSTRACT

A photovoltaic module conductor supporting structure that can be used to secure the conductor during manufacturing and in some situations to seal the terminal-area opening.

### CROSS REFERENCE TO RELATED APPLICATION

This application claims priority under 35 U.S.C. §119(e) to U.S. Provisional Patent Application Ser. No. 61/514,781 filed on Aug. 3, 2011, the subject matter of which is hereby incorporated by reference in its entirety.

### TECHNICAL FIELD

This invention relates to a photovoltaic module having a conductor support. The conductor support can include a means to establish a terminal area seal.

### BACKGROUND

Photovoltaic (PV) devices convert sunlight energy directly into electricity. As with all electrical devices, PV devices are usually provided with electrical conductive leads. One end of the leads is connected to electrical contacts within the PV devices and the other end of the electrical leads exits the PV devices to allow the devices to be connected to other external electrical devices.

Correctly positioning the electrically conductive leads and providing a water resistant opening where the leads exit the module can be important.

### DESCRIPTION OF DRAWINGS

FIG. 1A illustrates an angled view of a conductor where it exits a photovoltaic module, with point contacts.

FIG. 1B illustrates a top view of a conductor where it exits a photovoltaic module, with point contacts.

FIG. 2A illustrates an angled view of a conductor where it exits a photovoltaic module, with an improved contact surface.

FIG. 2B illustrates a top view of a conductor where it exits a photovoltaic module, with an improved contact surface.

FIG. 3 illustrates top views of alternate conductor support configurations.

FIG. 4 illustrates an angled view of a 1-piece insert that is designed to support conductive elements and to establish a terminal area seal.

FIG. 5 illustrates an angled view of a 2-piece insert that is designed to support conductive elements and to establish a terminal area seal.

FIG. 6 illustrates an angled view of a 2-piece insert that is designed to support conductive elements and to establish a terminal area seal.

### DETAILED DESCRIPTION

Photovoltaic devices can be formed on an optically transparent substrate, such as glass. Because glass is not conductive, a transparent conductive oxide (TCO) layer is typically formed between the substrate and a semiconductor bi-layer. Semiconductor bi-layers usually include a semiconductor absorber layer where light energy is absorbed and causes electrons to move and create current. The TCO layer along with the glass substrate allows light to pass through to the semiconductor bi-layer to produce the current. PV devices also include an electrically conductive back contact layer adjacent to the semiconductor absorber layer. The TCO layer serves as a front electrode while the back contact layer serves as a back electrode, and together they facilitate transfer of the created current outside of the PV devices. The PV devices can further include a back cover adjacent to the back contact layer. The back cover layer along with the glass substrate protects the PV devices from moisture intrusion, physical damage, or environmental hazards.

PV devices include cells, modules, etc. A PV module contains a plurality of PV cells. The plurality of the PV cells can be electrically connected in series, in parallel, or a combination thereof depending on the desired electrical output of the module. To do so, electrical conductors are used. Electrical conductors are also connected to the front and back electrodes of the module and exit the module through a cover plate opening therein to allow for module to module interconnectivity and/or connectivity with other electrical devices. The electrical conductors can include a flexible conductor that can be easily bent through the cover plate opening. A suitable electrical conductor can be a strip of lead foil, tin plated copper foil, silver plated copper foil, bare silver foil, or bare copper foil.

One of the challenges in designing PV devices with strips of foil as connectors has been to maintain the physical and electrical integrity of the conductor transversing the opening. Another challenge has been to provide accurate positioning of the external end of each lead foil for automated connection to an external conductor.

To address these challenges, a back cover opening insert has been developed that maintains the integrity of the lead foil, provides accurate positioning of the external end of the lead foil, and seals the photovoltaic module back cover opening around the conductive elements.

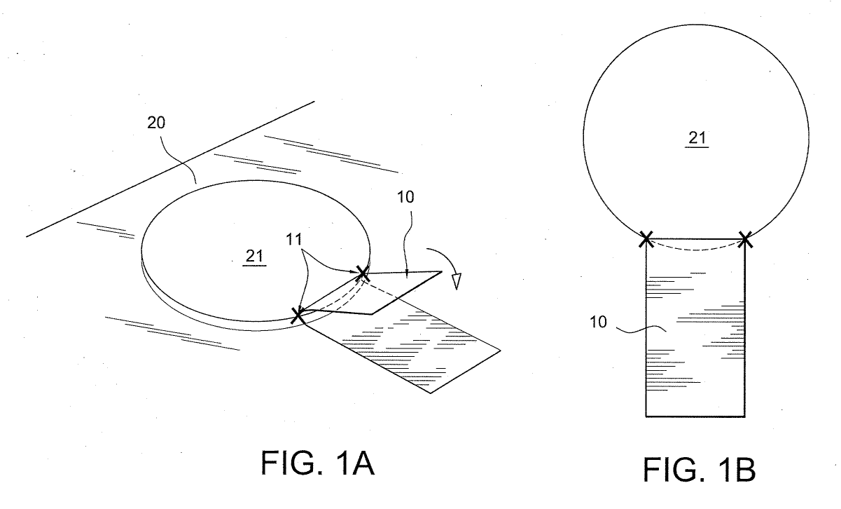

FIGS. 1A and 1B show a photovoltaic module manufacturing process. The process involves pulling positive and negative electrical conductors such as lead foils 10 through a circular opening 21 in a module construction (i.e. cover glass) 20 so that external ends of the lead foils 10 go through opening 21 on the external side of cover glass 20. Lead foils 10 can then be bent so they conform to the outer surface of cover glass 20 in preparation for terminal housing/cord plate application and soldering. The manufacturing process can involve two localized contact points 11 between metal and glass for each lead foil. Because there is no support for the lead foils 10 at the two contact points 11, even a relatively small amount of force can cause damage to the conductors or lead foils 10. A typical damaged conductor can be partly broken. Damaged conductors can be a source of reduced module performance because their series resistance may increase.

The cover glass opening is typically circular to minimize the formation of unnecessary crack propagation points in the glass that would be present with more complicated geometries. As a result, machining an opening with two flattened sides into a piece of cover glass is not a preferred approach.

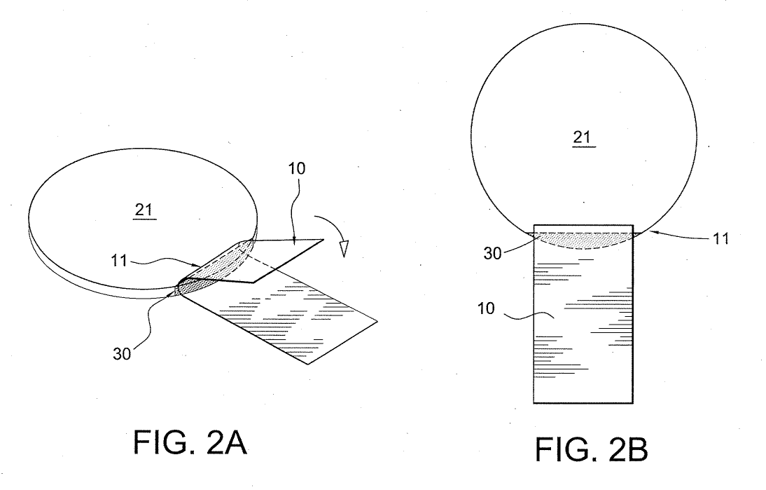

In some embodiments, as a method of modifying the shape of the cover glass opening, a nonconductive insert 30 can be placed into cover glass opening 21. The nonconductive insert 30 can create even edge 11 for lead foil 10 to be folded over, thereby distributing any forces along entire contact line/surface 11. As shown in FIGS. 2A, and 2B, lead foil 10 is folded over even edge 11 to distribute the force. As a result, the chance of damaging the lead foil can be reduced.

Manufacturing processes do not always involve sealing the cover glass opening where the conductor(s) exit the module. Instead a void is left in the final product that may later create a potential path for water ingress. The sensitivity of various solar cell technologies to water has been extensively studied. Under extreme conditions, the loss of active area can occur if moisture levels in the module pass a certain threshold, which may decrease module-level performance.

In some embodiments, a one-piece insert design may be used. The one-piece insert can have dual-functionality, capable of supporting each lead foil during manufacturing and sealing the cover glass opening after lamination and/or other thermal processing steps of photovoltaic module manufacture process.

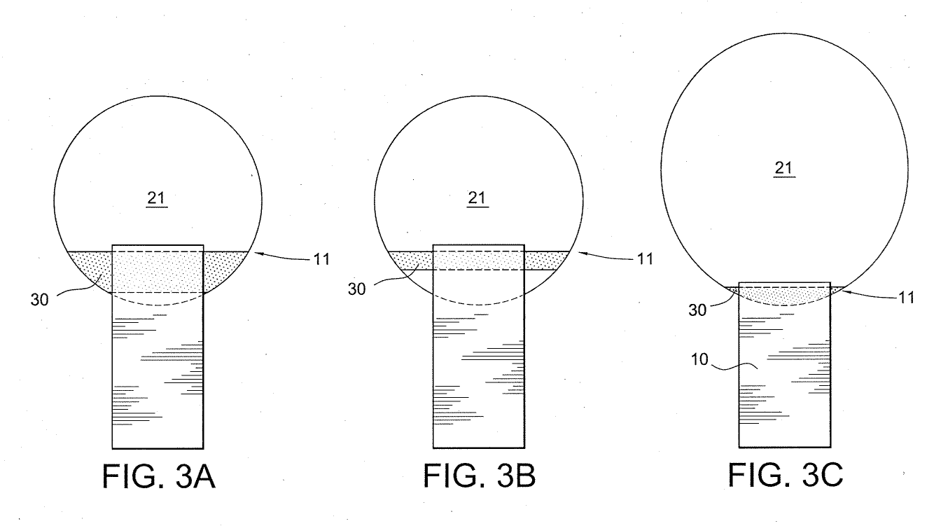

Additionally, insert 30 can have any suitable configuration to fit in any suitable opening. As shown in FIG. 3A, insert 30 can have a first edge, which can be substantially straight as defined by the edge 11 forming a contact line between insert 30 and lead foil 10. Note that by moving contact points 11 up or down along the circular opening 21, insert 30 can be as large as the diameter of the opening or as small as the width of the lead foil (see FIGS. 3A, 3B and 3C). Thus, the second edge of insert 30 can contact a greater or smaller portion of the edge of opening 21. As shown in FIG. 3B, insert 30 can have any suitable shape. For example, insert 30 can have a second and third arcuate (arc-shaped) edges configured to contact opposite sides of opening 21. Insert 30 can have a fourth edge substantially parallel to the first edge defined by contact points 11, creating a gap between the fourth edge and an edge of opening 21. As shown in FIG. 3C, insert 30 can be configured to fit in any suitable opening 21. For example, opening 21 can have a shape such as an elliptical shape. As a result, the second edge of insert 30 can have a congruous shape that allows at least a portion of the second edge to contact opening 21.

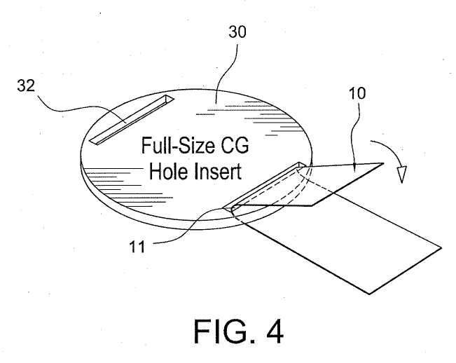

As shown in FIG. 4, insert 30 can be inserted into the cover glass opening, with slots 32 positioned for each lead foil 10.

Insert 30 can include a polymer for its flexibility and low cost. Candidate polymers may be either thermoplastic (i.e. acrylic, polycarbonate, ABS, polyolefins, nylon, PVB, PET, etc.) or thermoset (i.e. EVA, epoxies with solid-state resin and a heat-activated hardener component, etc.) in nature. Insert 30 can be made from any material with suitable processing temperatures, rheological (deformation) properties, adhesion strength, long-term durability, cost, moisture barrier performance, hardness, relative thermal index, dielectric strength, flammability rating, etc. It should be noted that proper rheological (deformation) properties are critical in order to facilitate completely sealing the opening and filling any. gaps. For example, insert 30 can be made from thermoplastics materials such as acrylic, polycarbonate, ABS, PE, PP, and other polyolefms or thermoset materials such as EVA and epoxies with a solid-state resin & heat-activated hardener component. Depending on the module design requirements, desiccant can be added to the insert formulation in order to further improve its moisture breakthrough time. In other words, desiccant can be used to lower its moisture absorption rate. Desiccants include but are not limited to molecular sieves, aluminum oxide, silica gel, calcium oxide, clay, and calcium sulfate.

In some embodiments, the insert must be designed so it does not interfere with air evacuation during lamination process of photovoltaic module manufacture. Also, the insert can be made using a high-temperature thermoplastic material (with melt transitions temperature well outside the normal range of lamination temperatures typically used for solar module manufacturing) if specialized techniques are used to melt the material after the conductor is positioned and stabilized. For instance, if the high-temp thermoplastic e.g. fluoropolymers is loaded with appropriate microwave susceptor particles that can absorb electromagnetic energy and convert it to heat, induction heating can be used to melt the insert. Induction heating can be a process of heating the insert by electromagnetic induction.

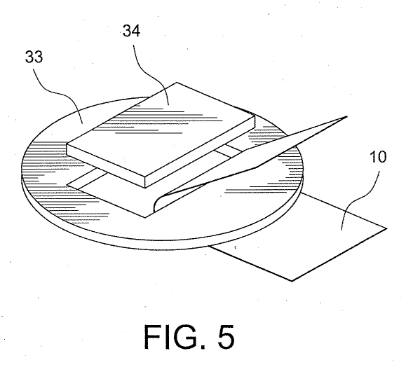

In some embodiments, as indicated in FIG. 5, a two-piece insert (33 and 34) can be used with dual-functionality. For instance, the two-piece insert can be used both to support each lead foil during manufacturing and to seal the cover glass opening after lamination and/or other thermal processing steps.

This can be especially useful for use with some available manufacturing processes, where first insert 33 is placed into the cord plate opening prior to trimming lead foils 10. The region of the insert that makes contact with the lead foil can be curved in order to further reduce any chance of damaging the lead foil. In addition, this two-piece insert can have a curved lead foil contact surface. Either before or after the lead foil is trimmed, second insert 34 can be inserted in order to hold lead foil 10 in place and to ensure proper sealing after lamination. If necessary, any suitable sealant or pottant can be used to seal first insert 33 and/or second insert 34.

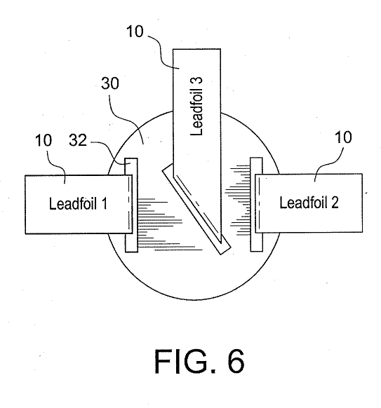

In some embodiments, there can be more than two conductors positioned in the opening. Referring to FIG. 6, insert 30 can have three slots 32 positioned for three lead foils 10. In some embodiments, insert 30 can have a plurality of slots 32 in any suitable arrangement.

It should be appreciated that insert 30 is not limited to use in photovoltaic modules, but can be used in any device that includes a conductor. The conductor can include a conductive tape such as a lead foil, that transverses an opening in a component, such as a cover. For example, insert 30 can be used in the cover of a flat-panel display, batteries, or any other suitable device.

In one aspect, a conductor support can include an insert configured to be positioned in an opening in a cover. The insert can include a first edge configured to contact a surface of a conductor and direct a conductor from the opening along a surface of a cover. The insert can include a second edge including a shape that corresponds to at least a portion of an edge of an opening in a cover, such that the second edge can contact a portion of an opening in a cover when the insert is positioned in an opening in a cover.

The first edge of the insert can be configured to contact a surface of a photovoltaic module conductor and direct a photovoltaic module conductor through the opening along a surface of a photovoltaic module cover. The second edge of the insert can include a shape that corresponds to at least a portion of an edge of an opening in a photovoltaic module cover, such that the second edge can contact a portion of an opening in a photovoltaic module cover when the insert is positioned in an opening in a photovoltaic module cover.

The insert can include a non-conductive material. The first edge can have a radius of curvature greater than a radius of curvature of the opening in a cover into which the insert is configured to fit. The first edge can include a substantially straight edge configured to contact a surface of a substantially flat conductor. The second edge can include an arc configured to contact an arcuate portion of an opening in a cover. The insert can have a thickness of between about 0.5 mm and about 5 mm.

The insert can be configured to contact most of the perimeter of an opening in a cover. The insert can include a disk configured to contact most of the perimeter of a substantially circular opening in a cover. The insert can include a slot comprising the first insert edge configured to contact a surface of a conductor. The slot can be configured to accept a second insert to secure a conductor between the insert and the second insert. The first edge can be rounded to prevent a conductor from being bent when it is contacted by the first edge.

In another aspect, a photovoltaic module can include a substrate, a plurality of photovoltaic cells adjacent to the substrate, and a back contact layer adjacent to the photovoltaic cells. The photovoltaic module can include a first lead foil adjacent to the back contact layer. The first lead foil can include an external end. The photovoltaic module can include a back cover including an opening adjacent to the first lead foil. The photovoltaic module can include a lead foil support including an insert having first edge and a second edge corresponding to the shape of the opening. The lead foil support can be positioned in the opening by contacting the second edge of the lead foil support adjacent to a portion of the opening. The lead foil can transverse the opening by contacting the first edge of the lead foil support and being directed along the external surface of the back cover.

The first edge can include a straight edge. The second edge can include an arc configured to contact an arcuate portion of an opening in a photovoltaic module cover. The insert can be configured to contact most of the perimeter of an opening in a photovoltaic module cover. The insert can include a disk configured to contact most of the perimeter of a substantially circular opening in a photovoltaic module cover. The insert can include a slot comprising the first insert edge configured to contact a surface of a photovoltaic module conductor. The photovoltaic module can include a second lead foil adjacent to the back contact layer, wherein the second lead foil comprises an external end. The lead foil support can include a third edge configured to support the second lead foil. The lead foil support can include a second slot comprising the third edge.

In another aspect, a method for manufacturing an electrical apparatus having a conductive lead and an opening through which the conductive lead passes can include positioning a conductive lead adjacent to surface of the apparatus and positioning a cover adjacent to the conductive lead and the surface, wherein the cover comprises an opening. The method can include positioning a conductor support adjacent to the cover opening and pulling a portion of conductive lead up through the cover opening. The method can include bending the portion of the conductive lead toward an external surface of the cover, the conductor support contacting the conductive lead.

The electrical apparatus can include a photovoltaic module including a photovoltaic module cover. The photovoltaic module cover can include a cover glass and/or a polymeric backing assembly. The conductive lead can include a lead foil or a bulbar. The opening can include a shape such as a circle, a rectangle, a square, a triangle, a shape with rounded corners, and/or an ellipse.

The method can include sealing the cover opening with the conductor support. The method can include sealing the cover opening by inserting a seal into the cover opening. The method can include melting the conductor support to seal the cover opening. The conductor support can form a substantially straight contact line for the conductor to be bent over. The conductor support can be non-conductive. The conductor support can include a polymeric disk, with the disk inserted into the module cover opening. The polymeric disk can include at least one slot, with the conductive lead being pulled through the slot. The conductive lead can include one or more of tin plated copper, silver plated copper, silver and copper. The conductive lead can include an adhesive backing.

While the invention has been shown and explained in the embodiment described herein, it is to be understood that the invention should not be confined to the exact showing of the drawings, and that any variations, substitutions, and modifications are intended to be comprehended within the spirit of the invention. Other embodiments are within the claims.

What is claimed is:

1. A support mechanism for an electrical conductor of an electrical device comprising:
an insert configured to be positioned in an opening in a cover of the electrical device, the insert including:
a first edge configured to contact a surface of the conductor and direct the conductor through the opening and along a surface of the cover; and
a second edge having a shape that corresponds to at least a portion of an edge of the opening in the cover that allows the second edge to contact a portion of the opening in the cover when the insert is positioned in the opening in the cover.

2. The support mechanism for claim 1, wherein the conductor is foil.

3. The support mechanism for claim 1, wherein the insert is configured to contact most of the perimeter of an opening in a cover.

4. The support mechanism of claim 3, wherein the cover is a back cover and the electrical device is a photovoltaic device.

5. The support mechanism of claim 1, wherein the insert protects against moisture ingress.

6. The support mechanism of claim 1, wherein the insert is a nonconductive material.

7. The support mechanism of claim 1, wherein the insert comprises a thermoplastic material.

8. The support mechanism of claim 1, wherein the first edge has a radius of curvature greater than the radius of curvature of the opening in a cover into which the insert is configured to fit.

9. The support mechanism of claim 1, wherein the first edge comprises a substantially straight edge configured to contact a surface of a substantially flat conductor.

10. The support mechanism of claim 1, wherein the insert has a thickness of between about 0.5 mm and about 5 mm.

11. The support mechanism of claim 9, wherein the insert comprises a slot comprising the first insert edge configured to contact a surface of a conductor.

12. The support mechanism of claim 11, wherein the slot is configured to accept a second insert to secure a conductor between the insert and the second insert.

13. The support mechanism of claim 1, wherein the first edge is rounded with a certain radius to prevent a conductor from being bent when it is contacted by the first edge.

14. A method for protecting a photovoltaic (PV) device from moisture comprising:
providing an insert configured to be positioned in an opening in a cover of the PV device to seal the opening, the insert including:
a first edge configured to contact a surface of an electrical conductor of the PV device and to direct the conductor through the opening and along a surface of the cover; and
a second edge having a shape that corresponds to at least a portion of an edge of the opening in the cover that allows the second edge to contact a portion of the opening in the cover when the insert is positioned in the opening in the cover.

15. The method of claim 14, wherein the insert further serves as a support mechanism for the electrical conductor.

16. The method of claim 14, wherein desiccant are added to the insert in order to further protect the PV device from moisture breakthrough time.

17. A photovoltaic module comprising:
a substrate;
a plurality of photovoltaic cells adjacent to the substrate;
a back contact layer adjacent to the photovoltaic cells;
a first lead foil adjacent to the back contact layer, wherein the first lead foil comprises an external end;
a back cover comprising an opening adjacent to the first lead foil; and
a lead foil support comprising an insert having first edge and a second edge corresponding to the shape of the opening, wherein the lead foil support is positioned in the opening by contacting the second edge of the lead foil support adjacent to a portion of the opening;
wherein the lead foil transverses the opening by contacting the first edge of the lead foil support and being directed along the external surface of the back cover.

18. The photovoltaic module of claim 17, wherein the first edge comprises a straight edge.

19. The photovoltaic module of claim 17, wherein the second edge comprises an arc configured to contact an arcuate portion of an opening in a photovoltaic module cover.

20. The photovoltaic module of claim 17, wherein the insert is configured to contact most of the perimeter of an opening in a photovoltaic module cover.

21. The photovoltaic module of claim 20, wherein the insert comprises a disk configured to contact most of the perimeter of a substantially circular opening in a photovoltaic module cover.

22. The photovoltaic module of claim 20, wherein the insert comprises a slot comprising the first insert edge configured to contact a surface of a photovoltaic module conductor.

23. The photovoltaic module of claim 17, further comprising a second lead foil adjacent to the back contact layer, wherein the second lead foil comprises an external end.

24. The photovoltaic module of claim 23, wherein the lead foil support comprises a third edge configured to support the second lead foil.

25. The photovoltaic module of claim 24, wherein the lead foil support comprises a second slot comprising the third edge.

26. A method for manufacturing an electrical apparatus having a conductive lead and an opening through which the conductive lead passes, comprising:
positioning a conductive lead adjacent to surface of the apparatus;
positioning a cover adjacent to the conductive lead and the surface, wherein the cover comprises an opening;
positioning a conductor support adjacent to the cover opening;
pulling a portion of conductive lead up through the cover opening; and
bending the portion of the conductive lead toward an external surface of the cover, the
conductive lead support contacting the conductive lead.

27. The method of claim 26, wherein the electrical apparatus comprises a photovoltaic module comprising a photovoltaic module cover.

28. The method of claim 27, wherein the photovoltaic module cover comprises a cover glass.

29. The method of claim 28, wherein the photovoltaic module cover comprises a polymer backing assembly.

30. The method of claim 26, wherein the conductive lead comprises a lead foil or a busbar.

31. The method of claim 26, wherein the opening comprises a shape selected from the group consisting of a circle, a rectangle, a square, a triangle, a shape with rounded corners, and an ellipse.

32. The method of claim 26, further comprising sealing the cover opening with the conductor support.

33. The method of claim 32, further comprising sealing the cover opening by inserting a seal into the cover opening.

34. The method of claim 32, further comprising melting the conductor support to seal the cover opening.

35. The method of claim 26, wherein the conductor support forms a substantially straight contact line for the conductor to be bent over.

36. The method of claim 26, wherein the conductor support is non-conductive.

37. The method of claim 26, wherein the conductor support comprises a polymeric disk, the polymeric disk being inserted into the cover opening.

38. The method of claim 37, wherein the polymeric disk comprises at least one slot, the conductive lead being pulled through the slot.

39. The method of claim 26, wherein the conductive lead comprises one or more of tin plated copper, silver plated copper, silver and copper.

40. The method of claim 26, wherein the conductive lead comprises an adhesive backing.
